(19) United States
(12) Patent Application Publication
(10) Pub. No.: US 2024/0347348 A1
(43) Pub. Date: Oct. 17, 2024

(54) PACKAGE STRUCTURE AND MANUFACTURING METHOD THEREOF

(71) Applicant: Powertech Technology Inc., Hsinchu County (TW)

(72) Inventor: Shang-Yu Chang Chien, Hsinchu County (TW)

(73) Assignee: Powertech Technology Inc., Hsinchu County (TW)

(21) Appl. No.: 18/427,834

(22) Filed: Jan. 31, 2024

(30) Foreign Application Priority Data
Apr. 13, 2023 (TW) 112113844

(51) Int. Cl. H01L 21/48; H01L 21/56; H01L 23/00; H01L 23/31; H01L 23/498; H01L 25/00; H01L 25/065

(52) U.S. Cl. CPC H01L 21/486; H01L 21/4853; H01L 21/561; H01L 21/563; H01L 23/3185; H01L 23/49827; H01L 25/0655; H01L 25/50; H01L 24/16; H01L 24/32; H01L 24/73; H01L 2224/16227; H01L 2224/32225; H01L 2224/73204

(57) ABSTRACT

A package structure and a manufacturing method thereof are provided. The package structure includes a redistributed circuit structure, a plurality of chips, a second encapsulant, a plurality of supporting members, a first encapsulant, and a plurality of connection terminals is provided. The redistributed circuit structure has a first surface and a second surface opposite to each other. The chips are disposed on the second surface of the redistributed circuit structure. The second encapsulant is disposed on the second surface of the redistributed circuit structure and covers the chips. The supporting members are disposed on the first surface of the redistributed circuit structure. The first encapsulant is disposed on the first surface of the redistributed circuit structure and covers the supporting members. The connection terminals are connected to the supporting members.

### CROSS-REFERENCE TO RELATED APPLICATION

This application claims the priority benefit of Taiwanese application no. 112113844, filed on Apr. 13, 2023. The entirety of the above-mentioned patent application is hereby incorporated by reference herein and made a part of this specification.

### BACKGROUND

### Technical Field

The disclosure relates to a package structure and a manufacturing method thereof. Particularly, the disclosure relates to a package structure having a supporting member and a manufacturing method thereof.

### Description of Related Art

With the advancement of science and technology, requirements for electronic products by the market are also increasingly trending toward lightweight, thinness, smallness, and portability. As a result, how to reduce the overall thickness of a package structure that includes a chip and maintain at least the quality of the package structure has currently become a subject of research.

### SUMMARY

The disclosure provides a package structure which has a relatively efficient or simple manufacturing process or has relatively favorable yield. In addition, the package structure may have relatively favorable quality.

In an embodiment of the disclosure, a package structure includes a redistributed circuit structure, a plurality of chips, a second encapsulant, a plurality of supporting members, a first encapsulant, and a plurality of connection terminals. The redistributed circuit structure has a first surface and a second surface opposite to each other. The plurality of chips are disposed on the second surface of the redistributed circuit structure. The second encapsulant is disposed on the second surface of the redistributed circuit structure and covers the plurality of chips. The plurality of supporting members are disposed on the first surface of the redistributed circuit structure. The first encapsulant is disposed on the first surface of the redistributed circuit structure and covers the plurality of supporting members. The plurality of connection terminals are connected to the plurality of supporting members.

In an embodiment of the disclosure, a manufacturing method of a package structure includes the following. A plurality of supporting structures and a first encapsulating material are formed on a carrier. A redistributed circuit structure is formed on the plurality of supporting structures and the first encapsulating material. A plurality of chips are disposed on the redistributed circuit structure. A second encapsulating material covering the plurality of chips is formed on the redistributed circuit structure. After the second encapsulating material is formed, a portion of the second encapsulating material is removed to form a second encapsulant, a portion of the first encapsulating material is removed to form a first encapsulant, and a portion of each of the supporting structures is removed to form a plurality of supporting members. A plurality of connection terminals connected to the plurality of supporting members are formed.

Based on the foregoing, during the manufacturing process of the package structure of the embodiments of the disclosure, by the supporting structure and the first encapsulating material covering the same (i.e., a structure corresponding to the supporting member embedded in the first encapsulant), it is possible to provide relatively favorable yield of the overall process of the package structure, and it is possible to reduce the overall thickness of the package structure or improve the quality of the package structure.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A to FIG. 1G are schematic partial cross-sectional views of part of a manufacturing method of a package structure according to the first embodiment of the disclosure.

FIG. 1H is a schematic partial cross-sectional view of a package structure according to the first embodiment of the disclosure.

FIG. 1I is a schematic partial cross-sectional view of a package structure according to the first embodiment of the disclosure.

FIG. 2 is a schematic partial cross-sectional view of a package structure according to the second embodiment of the disclosure.

FIG. 3 is a schematic partial cross-sectional view of a package structure according to the third embodiment of the disclosure.

### DESCRIPTION OF THE EMBODIMENTS

Unless expressly stated otherwise, directional terms (e.g., up, down, top, bottom) are used herein for reference to the drawings only and are not intended to imply absolute orientation.

Unless expressly stated otherwise, any method described herein is in no way intended to be construed as requiring performance of its steps in a particular order.

Unless expressly stated otherwise, the singular forms “a,” “the,” “said,” and similar terms include plural references.

Terms such as “first”, “second”, and “third” and similar terms may be used to describe various elements, but these elements should not be limited by these terms. These terms are only used to distinguish one element from another, and do not limit an order of execution or a structural orientation.

Numerical values expressed in this specification or derivative relationships between numerical values (comparisons or trends of ratios) may include the numerical values per se and deviation values within a deviation range acceptable for people ordinarily skilled in the art. The deviation value may be one or more standard deviations in the manufacturing process or measuring process, or may be one or more calculation errors caused by the adopted number of digits, rounding of numbers, error propagation, or other factors in the calculation or conversion process.

The disclosure will be illustrated more comprehensively with reference to the drawings of the embodiments. However, the disclosure may also be embodied in many different forms and should not be construed as limited to the embodiments set forth herein. Thicknesses, dimensions, or sizes of layers or regions may be enlarged in the drawings for clarity. The same or similar reference numbers represent the same or similar elements, and will not be repeatedly described in the following paragraphs.

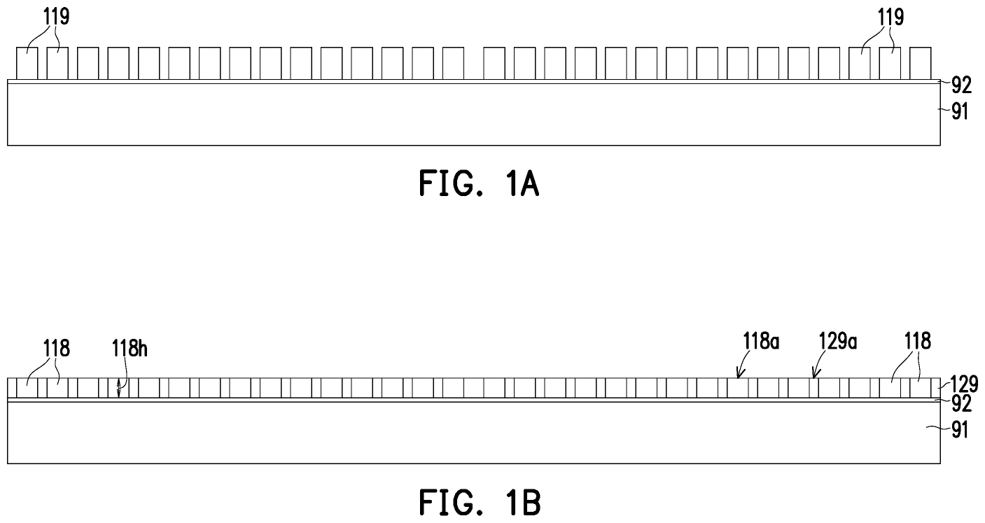

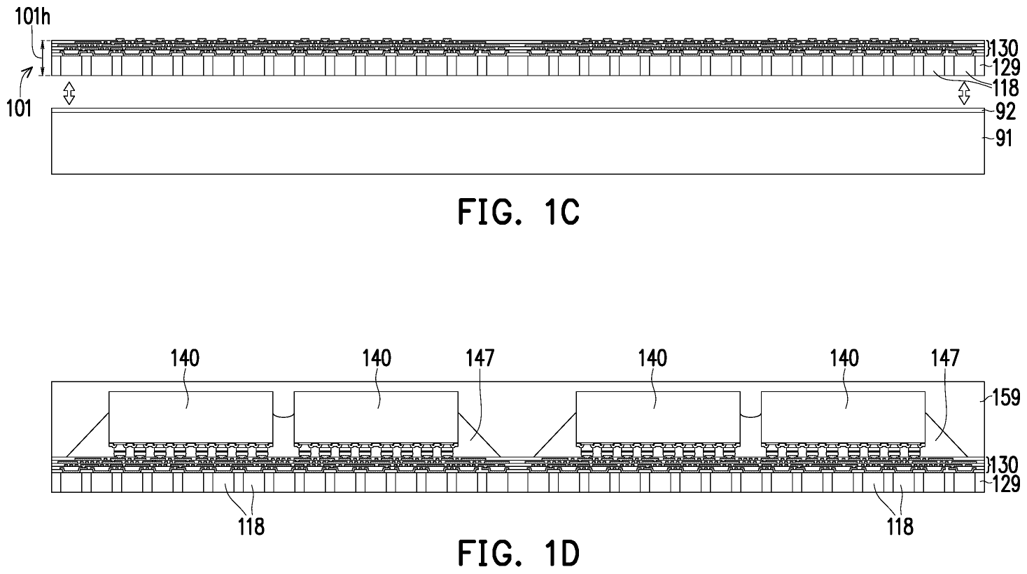

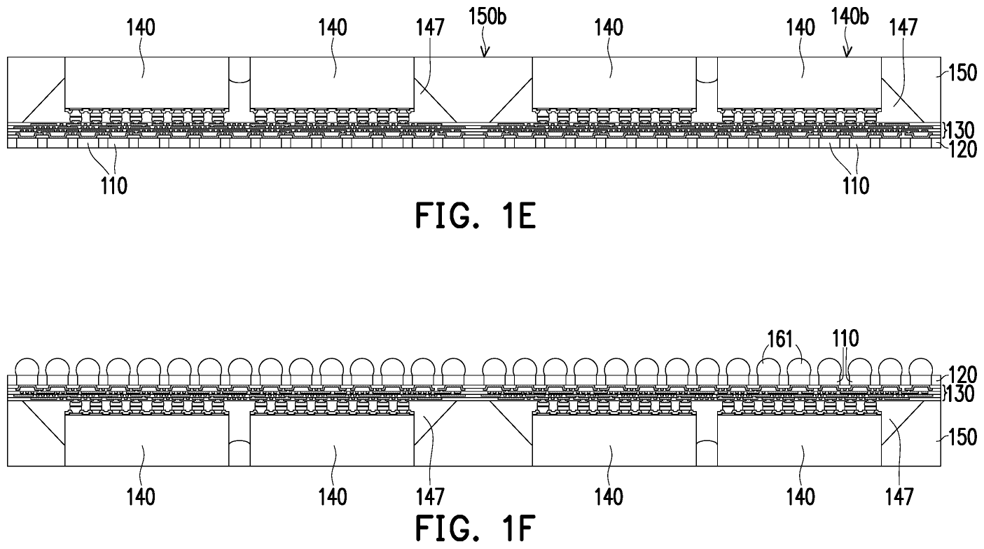

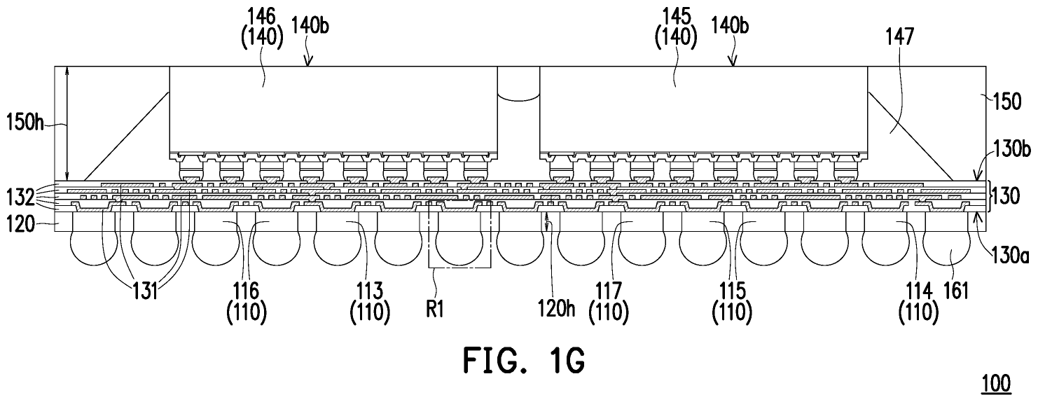

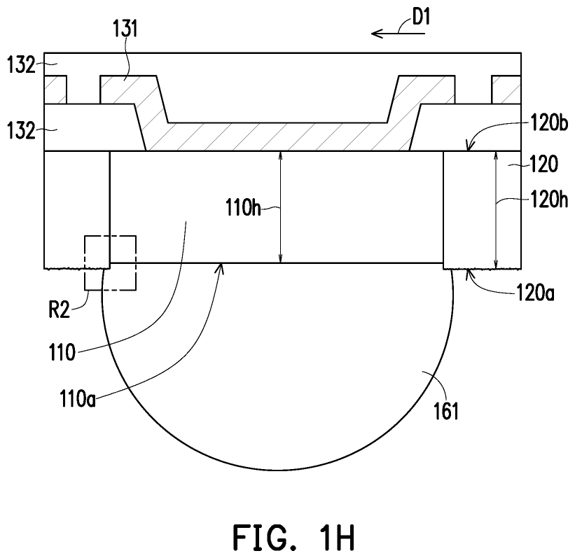

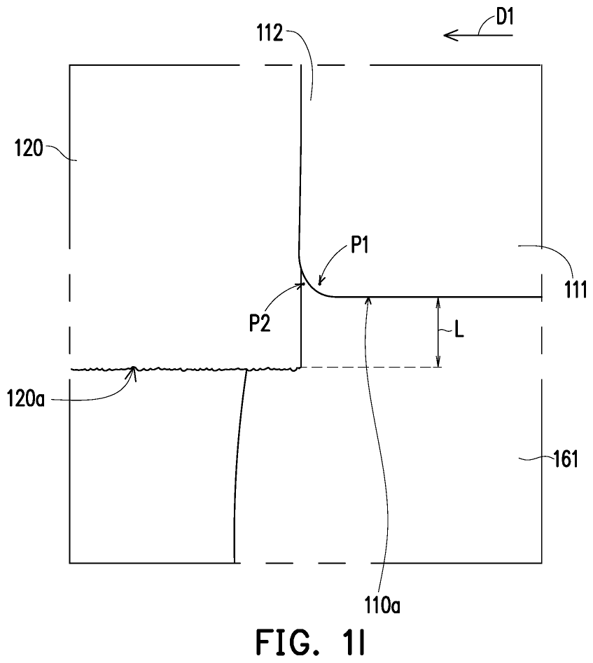

FIG. 1A to FIG. 1G are schematic partial cross-sectional views of part of a manufacturing method of a package structure according to the first embodiment of the disclosure.

With reference to FIG. 1A, a plurality of supporting structures 119 are disposed or formed on a carrier 91. The disclosure puts no special limitation on the carrier 91 as long as the carrier 91 may be suitable for supporting film layers formed thereon or elements disposed thereon.

In this embodiment, the carrier 91 may have a release layer 92 thereon, but the disclosure is not limited thereto. The release layer 92 is, for example, a light to heat conversion (LTHC) adhesive layer or other similar release layers, and the disclosure is not limited thereto.

In an embodiment, the supporting structure 119 may include a pre-formed conductive member. For example, the supporting structure 119 may include a pre-formed conductive pillar, but the disclosure is not limited thereto.

In an embodiment, the conductive pillar may include a copper pillar.

In an embodiment, the supporting structure 119 may be formed by commonly used semiconductor processes (e.g., a lithography process, a sputtering process, an electroplating process, and/or an etching process), but the disclosure is not limited thereto. For example, the supporting structure 119 may include a seed layer and a plating core layer disposed on the seed layer, but the disclosure is not limited thereto.

In an embodiment, the seed layer and/or the plating core layer may include a copper layer. For example, the seed layer may include a copper layer formed by a sputtering process, and the plating core layer may include a copper layer formed by an electroplating process.

In addition, not all supporting structures 119 are labeled in FIG. 1A for clarity.

With reference to FIG. 1A an FIG. 1B, an encapsulating material 129 is formed on the carrier 91.

In an embodiment, an organic material (e.g., a polyimide fry film (PI fry film), an epoxy mold compound (EMC), or a laminated Ajinomoto Build-up Film (laminated ABF)) may cover on the carrier 91. Then, in an appropriate manner (e.g., heating, pressing, and/or standing), the organic material is filled between the supporting structures 119 (labeled in FIG. 1A) or laterally covers the supporting structures 119 and is subsequently cured. Then, a planarization process may be performed to form the encapsulating material 129. The planarization process may be, for example, grinding, polishing, or other appropriate planarization steps.

In an embodiment, an organic material (e.g., a solder resist (SR)) may be coated on the carrier 91. Then, in an appropriate manner (e.g., standing and/or heating), the organic material is filled between the supporting structures 119 (labeled in FIG. 1A) or laterally covers the supporting structures 119 and is subsequently cured. Then, a planarization process may be performed to form the encapsulating material 129.

In an embodiment, during the planarization process, a portion of the supporting structures 119 (labeled in FIG. 1A; for example, a portion of the supporting structures 119 away from the carrier 91) may be slightly removed to form relatively short supporting structures 118 (labeled in FIG. 1B). In an embodiment, the encapsulating material 129 may expose atop surface 118a of the supporting structure 118, and a top surface 129a of the encapsulating material 129 and the top surface 118a of the supporting structure 118 are coplanar. In an embodiment, the top surface 118a may be referred to as a first supporting surface in the subsequent structure.

In an embodiment, a thickness 118h of the supporting structure 118 may be greater than or equal to 50 micrometers (μm). In this way, in the subsequent overall structure (e.g., a subsequent intermediate structure 101), a plurality of supporting structures 118 and the encapsulating material 129 laterally covering the supporting structures 118 may be suitable for serving as the main supporting component.

In addition, not all supporting structures 118 are labeled in FIG. 1B or other similar drawings for clarity.

With reference to FIG. 1B to FIG. 1C, a redistributed circuit structure 130 is formed on the top surface of the encapsulating material 129 and the top surface of the supporting structure 118. The redistributed circuit structure 130 may include a conductive layer 131 (labeled in FIG. 1G and/or FIG. 1H) and an insulation layer 132 (labeled in FIG. 1G and/or FIG. 1H). The redistributed circuit structure 130 may be formed by commonly used semiconductor processes (e.g., a coating process, a deposition process, a lithography process, and/or an etching process), which are thus not repeatedly described here. The numbers of layers of the conductive layer 131 and/or the insulation layer 132 are not limited by the disclosure. In addition, the forms of the conductive layer 131 and/or the insulation layer 132 are only exemplarily shown in the drawings (e.g., FIG. 1G and/or FIG. 1H). For example, even though two adjacent conductive layers 131 are not connected in the section shown in FIG. 1G, they may still be connected in other sections not shown. A corresponding portion in the conductive layer 131 may form a corresponding circuit. In addition, the layout design of the circuit may be adjusted depending on design requirements, and is not limited by the disclosure.

In addition, the conductive layer 131 and/or the insulation layer 132 are not directly labeled in FIG. 1C or other similar drawings for conciseness and clarity of the drawings. Reference may be made to FIG. 1G and/or FIG. 1H for portions of the conductive layer 131 and/or the insulation layer 132 in the redistributed circuit structure 130. In FIG. 1C or other similar drawings, the corresponding slashed framed region in the redistributed circuit structure 130 may be the corresponding conductive layer 131, and/or the corresponding blank framed region in the redistributed circuit structure 130 may be the corresponding insulation layer 132.

In this embodiment, a portion of the bottommost (here, the bottommost in the direction shown in FIG. 1C) conductive layer 131 in the redistributed circuit structure 130 may be in direct contact with, to be connected to, the top surface 118a of the corresponding supporting structure 118. In this way, the subsequent structure (e.g., the final structure of a package structure 100 or a certain portion of the structure during the manufacturing process of the package structure 100) may be relatively stabilized.

In an embodiment, the material of the insulation layer 132 of the redistributed circuit structure 130 is, for example, polyimide (PI), other appropriate organic insulating materials, or a stack or a combination thereof.

With further reference to FIG. 1C, the encapsulating material 129 and the supporting structure 118 are separated from the carrier 91 (for example, separated from the film layer (e.g., the release layer 92) on the carrier 91).

In an embodiment, the redistributed circuit structure 130 may first be formed; and then the encapsulating material 129 and the supporting structure 118 are separated from the carrier 91.

In an embodiment, if the plurality of supporting structures 118 and the encapsulating material 129 laterally covering the supporting structures 118 are sufficiently suitable for supporting, the encapsulating material 129 and the supporting structure 118 may first be separated from the carrier 91; and then the redistributed circuit structure 130 is formed.

In an embodiment, the separated structure may be regarded as the intermediate structure 101.

In an embodiment, the encapsulating material 129 and the supporting structure 118 may first be separated from the carrier 91; then, the separated structure may be appropriately cut, and a plurality of structures (each structure including the corresponding encapsulating material 129 and the supporting structure 118) after separated and subsequently cut may be regarded as a plurality of intermediate structures 101.

In an embodiment, the structure on the carrier 91 may first be appropriately cut; then, a plurality of structures (each structure including the corresponding encapsulating material 129 and the supporting structure 118) after cut are separated from the carrier 91, and the cut and subsequently separated structures may be regarded as a plurality of intermediate structures 101.

In an embodiment, the cut structures may have a relatively small warpage during the subsequent manufacturing process or in the corresponding structure. Moreover, it is possible to provide relatively favorable yield for the overall process of the package structure 100.

In an embodiment, in terms of the overall volume of the encapsulating material 129 and the supporting structure 118, the volume of the supporting structure 118 may be 10% to 40% of the overall volume (i.e., of the encapsulating material 129 and the supporting structure 118). In this way, bending or warpage of the intermediate structure 101 may be reduced. In an embodiment, the number and/or relative ratio of the supporting structure 118 may be adjusted depending on subsequent requirements (e.g., the number of contacts of a corresponding chip 140 (labeled in FIG. 1D or other similar drawings)), and/or may further be adjusted depending on the material of the encapsulating material 129.

In an embodiment, a coefficient of thermal expansion (CTE) of the material of the encapsulating material 129 is less than a CTE of the material of the redistributed circuit structure 130 (including the material of the insulation layer 132 and the material of the conductive layer 131). In this way, during a heating step on the redistributed circuit structure 130 (e.g., a heating step possible to be performed when subsequently disposing the chips 140 or curing the encapsulating material 129), the overall thermal expansion of the intermediate structure 101 may be reduced to improve the yield of the process of the package structure 100 and the quality of the package structure 100. Additionally, for a method of manufacturing a package structure, the encapsulating material 129 or a layer formed thereby (e.g., an encapsulant 120 as shown in FIG. 1E) contributes to good warpage control after the redistributed circuit structure 130 being formed. For example, a thicker EMC may resist shrinkage of a dielectric or insulation layer (e.g., the insulation layer 132 of the redistributed circuit structure 130 as shown in FIG. 1G) as it is cured and cooled down to room temperature.

In an embodiment, a thickness 101h of the intermediate structure 101 may be greater than or equal to 150 μm. In an embodiment, the intermediate structure 101 may already have a favorable stress tolerance in the subsequent process, and is sufficiently suitable for supporting film layers formed thereon or elements disposed thereon. In other words, the intermediate structure 101 may not need to be placed on a carrier (e.g., a carrier that is the same as or similar to the carrier 91) in the subsequent process. In this way, the manufacturing process of the package structure 100 may be relatively efficient or relatively simple.

With reference to FIG. 1D, a plurality of chips 140 are disposed on the redistributed circuit structure 130, such that the circuits in the chips 140 are electrically connected to the corresponding circuits in the redistributed circuit structure 130 (a portion of the conductive layer 131 of the redistributed circuit structure 130).

In an embodiment, the chips 140 may be disposed on the redistributed circuit structure 130 by flip chip bonding. For example, the active surfaces of the chips 140 may face the redistributed circuit structure 130. In addition, the chip connection pads of the chips 140 may be electrically connected to corresponding circuits in the redistributed circuit structure 130 through corresponding conductive connection members (e.g., solder balls).

With further reference to FIG. 1D, in an embodiment, a filler 147 may be formed between the chips 140 and the redistributed circuit structure 130. The filler 147 is, for example, a capillary underfill (CUF) or other appropriate filling materials, but the disclosure is not limited thereto.

In an embodiment, the filler 147 may be regarded as an encapsulating material.

With further reference to FIG. 1D, after the plurality of chips 140 are disposed on the redistributed circuit structure 130, an encapsulating material 159 is formed on the redistributed circuit structure 130. The encapsulating material 159 at least laterally covers each chip 140.

In an embodiment, a molding compound (e.g., epoxy; not shown) may be formed on the redistributed circuit structure 130. Then, the molding compound is cured in an appropriate manner (e.g., heating, lighting, and/or standing) to form the encapsulating material 159.

With further reference to FIG. 1D and FIG. 1E, a thinning step is performed on the structure as shown in FIG. 1D to form the structure as shown in FIG. 1E.

In an embodiment, a portion of the encapsulating material 159 (labeled in FIG. 1D) may be removed to form a second encapsulant 150 (labeled in FIG. 1E) laterally covering each chip 140. In an embodiment, a portion of the encapsulating material 159 (labeled in FIG. 1D) may be removed by an appropriate planarization step. In an embodiment, during the process of removing a portion of the encapsulating material 159 (labeled in FIG. 1D), a portion of the chips 140 (e.g., silicon substrates of the chips 140) may also be slightly removed. In an embodiment, a top surface 150b of the second encapsulant 150 and back surfaces 140b of the chips 140 are coplanar. The back surfaces 140b of the chips 140 are opposite to the active surfaces of the chips 140.

In an embodiment, a portion of the encapsulating material 129 (labeled in FIG. 1D) may be removed and a portion of the supporting structure 118 (labeled in FIG. 1D) may be removed to correspondingly form a first encapsulant 120 (labeled in FIG. 1E) and a supporting member 110 (labeled in FIG. 1E). In addition, not all supporting members 110 are labeled in FIG. 1E or other similar drawings for clarity.

In an embodiment, a portion of the encapsulating material 129 may be removed and a portion of the supporting structure 118 may be removed by the same step (e.g., an appropriate planarization step).

In an embodiment, after a portion of the encapsulating material 129 is removed and a portion of the supporting structure 118 is removed by the same step (e.g., an appropriate planarization step), a portion of the supporting structure 118 may further be removed by etching (e.g., wet etching) to correspondingly form the first encapsulant 120 (labeled in FIG. 1E) and the supporting member 110 (labeled in FIG. 1E). In this way, it is possible to reduce the likelihood that used reagents (e.g., slurry or other possible grinding materials) or removed objects (e.g., insulating particles produced by the removed encapsulant) adhere to the supporting member 110 during the process of removing a portion of the encapsulating material 129, and it is possible to improve the connection quality or conductive quality between the supporting member 110 and other elements in subsequent steps or structures. In addition, the supporting member 110 may be formed in a manner including etching. As a result, a thickness 110h (labeled in FIG. 1H) of the supporting member 110 is substantially smaller than a thickness 120h of the first encapsulant 120. In this way, an element directly connected to the supporting member 110 may be regarded as partially embedded in the first encapsulant 120, which may improve the connection quality between the supporting member 110 and the element.

In general semiconductor processes, the appearance of a surface after a planarization step (e.g., grinding or polishing) is performed on an object may be different from the appearance of a surface formed after an etching step (e.g., wet etching) is performed on the object.

For example, if a planarization step is performed on an object, the surface formed may have grinding marks; alternatively, generation or dimensions of the grinding marks may be reduced by adjustment of the grinding speed, adjustment of the grinding time, selection of the grinding slurry, and/or selection of the grinding pads. In addition, if an etching step is performed on an object, the surface formed may have an etching texture. In other words, a surface roughness of a surface 120a (labeled in FIG. 1H) of the first encapsulant 120 may be different from a surface roughness of a surface 110a (labeled in FIG. 1H) of the supporting member 110.

In addition, during the process of a wet etching step (which may include a wet clean step required after the wet etching step), there may be slight edge etching due to residue of the etching agent at the edge and/or residue at the interface. For example, the surface 110a of the supporting member 110 may be an etched surface, and the edge of the etched surface may have a corresponding curvature. For another example, as shown in FIG. 1I, in terms of a place on the surface 110a of the supporting member 110 close to the first encapsulant 120 (which may be referred to as a second portion 112), this place on the surface 110a of the supporting member 110 close to the first encapsulant 120 may be relatively recessed inward in a direction toward the redistributed circuit structure 130 compared with another place (which may be referred to as a first portion 111 surrounded by the second portion 112) on the surface 110a of the supporting member 110. In other words, a thickness of the first portion 111 may be greater than a thickness of the second portion 112. In an embodiment, the surface 110a may be referred to as a second supporting surface.

In an embodiment, a distance L between the surface of the supporting member 110 and the surface of the first encapsulant 120 may be less than or equal to 3 μm. For example, the distance L between the surface of the supporting member 110 and the surface of the first encapsulant 120 may range from 1 μm to 3 μm.

In an embodiment, a difference between the thickness 120h of the first encapsulant 120 and the thickness 110h of the supporting member 110 may be less than or equal to 3 μm. For example, the difference between the thickness 120h of the first encapsulant 120 and the thickness 110h of the supporting member 110 may range from 1 μm to 3 μm.

With further reference to FIG. 1E to FIG. 1F, a connection terminal 161 is formed on the supporting member 110. The connection terminal 161 may include a solder ball. For example, the structure as shown in FIG. 1E may be flipped upside-down; then, the connection terminal 161 directly connected to the supporting member 110 is formed in an appropriate manner (e.g., a ball mounting process). In addition, not all connection terminals 161 are labeled in FIG. 1F or other similar drawings for clarity.

In an embodiment, the material of the solder ball may include tin.

In an embodiment, the supporting member 110 may include a plating core layer and a seed layer, and the connection terminal may be in direct contact with the plating core layer.

With reference to FIG. 1F to FIG. 1G, in an embodiment, a cutting step may be performed on at least the first encapsulant 120, the redistributed circuit structure 130, and the second encapsulant 150 to form a plurality of package structures 100 as shown in FIG. 1G. The cutting step is, for example, cutting with a rotating blade or a laser beam, but the disclosure is not limited thereto. It should be noted that the order of forming the connection terminal 161 and performing the cutting step is not limited by the disclosure. For example, in this embodiment, the connection terminal 161 is first formed; and then the cutting step is performed. In an embodiment not shown, the cutting step may first be performed; and then the connection terminal 161 is formed.

It is worth noting that after the cutting step is performed, similar reference numerals will be used for the preliminary structure 101 after the cutting step. For example, the second encapsulant 150 (as shown in FIG. 1F) may be a plurality of second encapsulants 150 (as shown in FIG. 1G) after cutting, the plurality of chips 140 (as shown in FIG. 1F) may be a plurality of chips 140 (as shown in FIG. 1G) after cutting, the redistributed circuit structure 130 (as shown in FIG. 1F) may be a plurality of redistributed circuit structures 130 (as shown in FIG. 1G) after cutting, the first encapsulant 120 (as shown in FIG. 1F) may be a plurality of first encapsulants 120 (as shown in FIG. 1G) after cutting, the plurality of supporting members 110 (as shown in FIG. 1F) may be a plurality of supporting members 110 (as shown in FIG. 1G) after cutting, and so on. Elements in other package structures 100 will follow the same rules of reference numerals as above, and will not be repeatedly described or particularly shown here.

After the above process, the package structure 100 of this embodiment may be substantially completed.

FIG. 1G may be a schematic partial cross-sectional view of a package structure according to the first embodiment of the disclosure. FIG. 1H is a schematic partial cross-sectional view of a package structure according to the first embodiment of the disclosure. FIG. 1H may be a schematic enlarged view of region R1 in FIG. 1G. FIG. 1I is a schematic partial cross-sectional view of a package structure according to the first embodiment of the disclosure. FIG. 1I may be a schematic enlarged view of region R2 in FIG. 1H. In other words, where the package structure 100 is described, at least the contents shown in FIG. 1G, FIG. 1H, and FIG. 1I and the corresponding descriptions are required to be considered. Nonetheless, some structural details may be related to the process above. As a result, where the package structure 100 is described, the contents shown in FIG. 1A to FIG. 1G and the corresponding descriptions may further be considered.

With reference to FIG. 1G to FIG. 1I, the package structure 100 includes a redistributed circuit structure 130, a plurality of chips 140, a second encapsulant 150, a plurality of supporting members 110, a first encapsulant 120, and a plurality of connection terminals 161. The redistributed circuit structure 130 has a first surface 130a and a second surface 130b opposite to each other. The chips 140 are disposed on the second surface 130b (at the upper side of FIG. 1G) of the redistributed circuit structure 130. The second encapsulant 150 is disposed on the second surface 130b (at the upper side of FIG. 1G) of the redistributed circuit structure 130. The second encapsulant 150 laterally covers the chips 140 at least directly or indirectly. The supporting members 110 are disposed on the first surface (at the lower side of FIG. 1G) of the redistributed circuit structure 130. The first encapsulant 120 is disposed on the first surface (at the lower side of FIG. 1G) of the redistributed circuit structure 130. The first encapsulant 120 laterally covers the supporting members 110. The connection terminals 161 are connected to the supporting members 110.

In an embodiment, as shown in the drawings above, during the manufacturing process of the package structure 100, the supporting structure 118 may be embedded in the encapsulating material 129 (i.e., corresponding to a structure where the supporting members 110 are embedded in the first encapsulant 120). Moreover, in the package structure 100, a thickness 150h of the second encapsulant 150 is greater than the thickness 120h of the first encapsulant 120. In this way, it is possible to provide relatively favorable yield of the overall process of the package structure 100, and it is possible to reduce the overall thickness of the package structure 100.

In an embodiment, opposite ends of the supporting member 110 may respectively be in direct contact with the connection terminal 161 and a portion of the bottommost (here, the bottommost in the direction shown in FIG. 1G) conductive layer 131 of the redistributed circuit structure 130. In other words, the chip 140 may be electrically connected to the corresponding connection terminal 161 through the corresponding circuit (i.e., a certain portion of the conductive layer 131) in the redistributed circuit structure 130 and the corresponding supporting member 110. In this way, during the manufacturing process of the package structure 100, the supporting structure 118 (i.e., corresponding to the supporting member 110) and the encapsulating material 129 (corresponding to the first encapsulant 120) may serve as a structural support, and in the package structure 100, the supporting member 110 may serve as a portion suitable for electrical signal transmission.

In an embodiment, the thickness 120h of the first encapsulant 120 is greater than the thickness 110h of each supporting member 110, and/or a portion of each connection terminal 161 is embedded in the first encapsulant 120. In other words, the bottom surface 120a of the first encapsulant 120 is substantially not coplanar with the bottom surface 110a of the supporting member 110. In this way, the connection terminals 161 may have a relatively favorable connection, and/or the likelihood of ball drop during the manufacturing process or application process of the package structure 100 may be reduced.

In an embodiment, a portion of the plurality of supporting members 110 are overlapped with the plurality of chips 140. For example, a supporting member 115 (a portion of the plurality of supporting members 110) is overlapped with a chip 145 (a portion of the plurality of chips 140), and a supporting member 116 (a portion of the plurality of supporting members 110) is overlapped with a chip 146 (a portion of the plurality of chips 140).

In an embodiment, a supporting member 117 (a portion of the plurality of supporting members 110) may be electrically connected to the chip 145, a supporting member 113 (a portion of the plurality of supporting members 110) may be electrically connected to the chip 146, and a supporting member 114 (a portion of the plurality of supporting members 110) may be electrically separated from the chip 145 and the chip 146.

In an embodiment, the supporting member 114 may be a dummy component for signal processing or signal transmission of the package structure 100. In other words, a supporting member 114 substantially may not participate in signal processing or signal transmission.

It should be noted that the disclosure does not limit that the supporting member 114 is not electrically connected to any conductor. For example, in a possible embodiment, the supporting member 114 may be electrically connected to a shielding body through an appropriate circuit. In this way, the overall charge capacity of the shielding body and the conductor (e.g., the supporting member 114) electrically connected thereto may be increased.

In an embodiment, taking FIG. 1I as an example, in a conductive region without any insulating material between a top surface of the first encapsulant 120 and the bottom surface of the first encapsulant 120, the conductive region includes a first region P1 and a second region P2 in a direction D1 parallel to a top surface 120b (which may be referred to as a first encapsulating surface) or the bottom surface 120a (opposite to the top surface 120b; which may be referred to as a second encapsulating surface) of the first encapsulant 120, and the second region P2 is relatively close to the first encapsulant 120 compared with the first region P1. The first region P1 includes at least one of a first metal element or a second metal element. In the first region P1, the first metal element has a first ratio to the second metal element (e.g., the relative number of moles or its derivative unit of the first metal element within the detection range/the relative number of moles or its derivative unit of the second metal element within the detection range; which similarly applies later). The second region P2 includes at least one of the first metal element or the second metal element. In the second region P2, the first metal element has a second ratio to the second metal element. The first ratio is greater than the second ratio. The types or the corresponding concentrations of the metal elements may be measured by elemental analysis (e.g., energy-dispersive X-ray spectroscopy (EDS/EDX), but not limited thereto).

In an embodiment, between the first region P1 and the second region P2, the ratio of the first metal element to the second metal element may gradually decrease in a direction from the first region P1 to the second region P2. The gradient relationship between the elements between the two regions may be measured by EDS/EDX line analysis, for example.

It is worth noting that during the process of general measurement (e.g., measurement belonging to elemental analysis), the correspondingly measured values may have corresponding measured fluctuation within a deviation range (e.g., detection errors or sampling errors) of measurement acceptable for people ordinarily skilled in the art. As a result, analysis may be made through multiple times of measurement or further data statistical processing (e.g., eliminating outliers and/or multiple times of averaging) to reduce the measured fluctuation. For example, it may be necessary to perform multiple times (e.g., 10 times, 30 times, or 50 times) of measurement between the two regions to check the relationship between the elements between the two regions; then, data statistical processing is performed on the results of the multiple times of measurement to reduce the measured fluctuation, and the corresponding relationship may be obtained.

In an embodiment, the first metal element is copper and the second metal element is tin.

In an embodiment, the ratio relationship between the metal elements between the first region P1 and second region P2 may be formed by, for example (but not limited to), edge etching and/or an intermetallic compound (IMC) correspondingly formed during the manufacturing process of the package structure 100.

In an embodiment, the package structure 100 may be referred to as a substrate-less package.

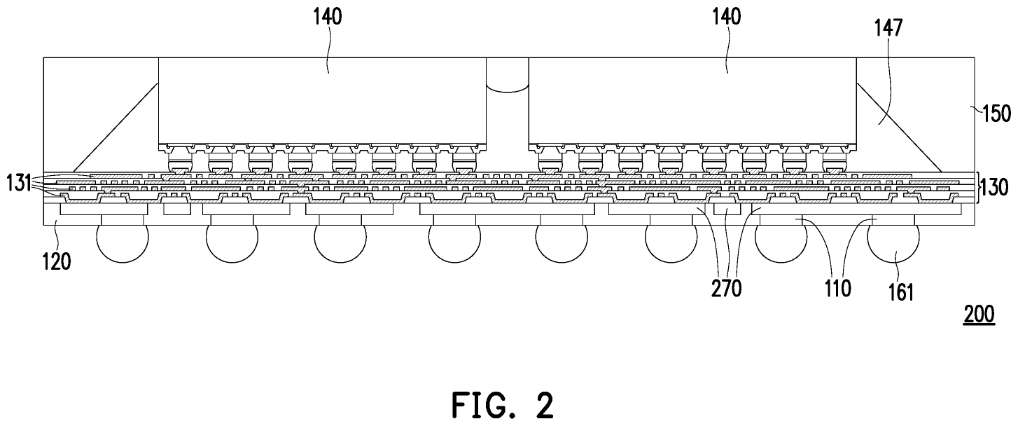

FIG. 2 is a schematic partial cross-sectional view of a package structure according to the second embodiment of the disclosure. A package structure 200 and a manufacturing method thereof in this embodiment are similar to the package structure 100 and the manufacturing method thereof in the first embodiment, with their similar components labeled by the same reference numerals, and have similar functions, materials, or formations, and the descriptions are omitted.

With reference to FIG. 2, the package structure 200 may include a redistributed circuit structure 130, a plurality of chips 140, a second encapsulant 150, a plurality of supporting members 110, a plurality of buffer members 270, a first encapsulant 120, and a plurality of connection terminals 161. The buffer member 270 may be disposed between the redistributed circuit structure 130 and the supporting members 110. A thickness of the buffer member 270 may be greater than a thickness of any conductive layer 131 in the redistributed circuit structure 130. The chip 140 may be electrically connected to the corresponding connection terminal 161 through the corresponding circuit (i.e., a certain portion of the conductive layer 131) in the redistributed circuit structure 130, the corresponding buffer member 270, and the corresponding supporting member 110.

In an embodiment, the buffer member 270 may include a thick metal sheet. For example, the buffer member 270 may include a commonly termed thick copper circuit. For another example, during the manufacturing process of the package structure 200, a thick metal sheet may first be disposed or formed on the supporting structure 118 to form the buffer member 270 disposed on the supporting member 110; and then the redistributed circuit structure 130 is formed on the buffer member 270. In addition, not all buffer members 270 are labeled in FIG. 2 for clarity.

In an embodiment, a portion of the buffer member 270 may be electrically connected to the chips 140, and another portion of the buffer member 270 may be electrically separated from the chips 140.

In an embodiment, a portion of the buffer member 270 that is not electrically connected to the chips 140 may be a dummy component for signal processing or signal transmission of the package structure 200. In other words, a portion of the buffer member 270 that is not electrically connected to the chips 140 substantially may not participate in signal processing or signal transmission.

It should be noted that the disclosure does not limit that a portion of the buffer member 270 that is not electrically connected to the chips 140 is not electrically connected to any conductor. For example, in a possible embodiment, a portion of the buffer member 270 that is not electrically connected to the chips 140 may be electrically connected to a shielding body through an appropriate circuit.

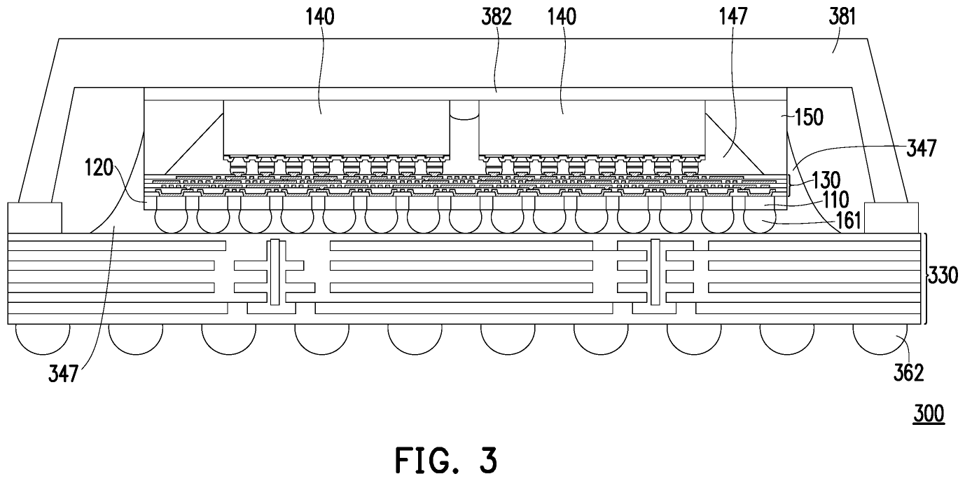

FIG. 3 is a schematic partial cross-sectional view of a package structure according to the third embodiment of the disclosure. A package structure 300 and a manufacturing method thereof in this embodiment are similar to the package structure 100 and the manufacturing method thereof in the first embodiment, with their similar components labeled by the same reference numerals, and have similar functions, materials, or formations, and the descriptions are omitted.

With reference to FIG. 3, the package structure 300 may include a redistributed circuit structure 130, a plurality of chips 140, a second encapsulant 150, a plurality of supporting members 110, a first encapsulant 120, a plurality of first connection terminals 161, a circuit board 330, a plurality of second connection terminals 362, and a casing 381. The first connection terminals 161 and the second connection terminals 362 may be respectively disposed on opposite sides of the circuit board 330. The casing 381 may be disposed on the circuit board 330. The plurality of chips 140 may be disposed within the accommodation space of the casing 381. In addition, not all second connection terminals 362 are labeled in FIG. 3 for clarity.

In this embodiment, the circuit board 330 may include a printed circuit board (PCB), a high density interconnect board (HDI board), an interposer, an ABF (Ajinomoto Build-Up Film) substrate, or other appropriate boards including a circuit, but the disclosure is not limited thereto. In addition, only some circuits in the circuit board 330 are schematically shown in the drawings for clarity.

In this embodiment, the chips 140 may be electrically connected to the corresponding second connection terminal 362 by the corresponding circuit in the redistributed circuit structure 130, the corresponding supporting member 110, the corresponding first connection terminal 161, and the corresponding circuit in the circuit board 330.

In this embodiment, there may be an adhesive layer 382 between the chips 140 and the casing 381.

In this embodiment, the casing 381 may include a heat-dissipating casing. For example, the adhesive layer 382 may be a thermally conductive adhesive layer. During the operation of the package structure 300, the chips 140 may be thermally coupled with the casing 381 through the thermally conductive adhesive layer, such that heat generated by the chips 140 may be dissipated relatively efficiently.

In this embodiment, the casing 381 may include an electromagnetic interference shielding (EMI shielding) casing 381 or other similar shielding bodies.

In an embodiment, at least one of the supporting members 110 may be electrically connected to the casing 381 through appropriate circuits (e.g., the corresponding first connection terminal 161 and the corresponding circuit in the circuit board 330).

In an embodiment, a filler 347 may be formed between the first encapsulant 120 and the circuit board 330. The filler 347 is, for example, a CUF or other appropriate filling materials, but the disclosure is not limited thereto.

In an embodiment, the filler 347 may further laterally cover the first encapsulant 120, the redistributed circuit structure 130, or the second encapsulant 150, but the disclosure is not limited thereto.

Components or elements in all drawings may be appropriately arranged and/or combined into members presented in another drawing not shown. In addition, additional components, elements, and/or their corresponding functionality may be added without departing from the disclosure. For example, in a certain package structure, FIG. 1G may be a schematic cross-sectional view on a certain section, and FIG. 2 may be a schematic cross-sectional view on another section. For example, the structure shown in FIG. 2 may be added with a certain component or element shown in FIG. 3.

In summary of the foregoing, during the manufacturing process of the package structure of the embodiments of the disclosure, by the supporting structure and the encapsulating material covering the same (i.e., a structure corresponding to the supporting member embedded in the encapsulant), it is possible to provide relatively favorable yield of the overall process of the package structure, and it is possible to reduce the overall thickness of the package structure or improve the quality of the package structure.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A package structure comprising:
a redistributed circuit structure having a first surface and a second surface opposite to each other;
a plurality of chips disposed on the second surface of the redistributed circuit structure;
a second encapsulant disposed on the second surface of the redistributed circuit structure and covering the plurality of chips;
a plurality of supporting members disposed on the first surface of the redistributed circuit structure;
a first encapsulant disposed on the first surface of the redistributed circuit structure and covering the plurality of supporting members; and
a plurality of connection terminals connected to the plurality of supporting members.

2. The package structure according to claim 1, wherein a thickness of the second encapsulant is greater than a thickness of the first encapsulant.

3. The package structure according to claim 1, wherein a thickness of the first encapsulant is greater than a thickness of the plurality of supporting members.

4. The package structure according to claim 3, wherein each of the supporting members comprises a first portion and a second portion surrounding the first portion, and a thickness of the first portion is different from a thickness of the second portion.

5. The package structure according to claim 1, wherein a portion of the connection terminals is embedded in the first encapsulant.

6. The package structure according to claim 1, wherein the first encapsulant has a first encapsulating surface and a second encapsulating surface opposite to each other, the plurality of supporting members have a first supporting surface and a second supporting surface opposite to each other, and the first encapsulating surface, the first supporting surface, and the first surface of the redistributed circuit structure are coplanar, and wherein
the second encapsulating surface and the second supporting surface are not coplanar;
the second supporting surface is not flat; or
the second supporting surface is an etched surface.

7. The package structure according to claim 1, wherein the first encapsulant has a second encapsulating surface away from the redistributed circuit structure, the plurality of supporting members have a second supporting surface far away from the redistributed circuit structure, and a roughness of the encapsulating surface is different from a roughness of the supporting surface.

8. The package structure according to claim 1, wherein a portion of the plurality of supporting members is overlapped with the plurality of chips.

9. The package structure according to claim 1, wherein a portion of the plurality of supporting members is electrically connected to the plurality of chips, and a portion of the plurality of supporting members is electrically separated from the plurality of chips.

10. A manufacturing method of a package structure, comprising:
forming a plurality of supporting structures and a first encapsulating material on a carrier;
forming a redistributed circuit structure on the plurality of supporting structures and the first encapsulating material;
disposing a plurality of chips on the redistributed circuit structure;
forming a second encapsulating material covering the plurality of chips on the redistributed circuit structure;
after forming the second encapsulating material, removing a portion of the second encapsulating material to form a second encapsulant, removing a portion of the first encapsulating material to form a first encapsulant, and removing a portion of each of the supporting structures to form a plurality of supporting members; and
forming a plurality of connection terminals connected to the plurality of supporting members.
